(19) United States
(12) Patent Application Publication
(10) Pub. No.: US 2013/0161657 A1
(43) Pub. Date: Jun. 27, 2013

(54) LIGHT EMITTING DIODE PACKAGE AND METHOD FOR MAKING SAME

(71) Applicants: Chao-Hsiung Chang, Hukou (TW); Hou-Te Lin, Hukou (TW)

(72) Inventors: Chao-Hsiung Chang, Hukou (TW); Hou-Te Lin, Hukou (TW)

(73) Assignee: ADVANCED OPTOELECTRONIC TECHNOLOGY, INC., Hsinchu Hsien (TW)

(21) Appl. No.: 13/527,596

(22) Filed: Jun. 20, 2012

(30) Foreign Application Priority Data
Dec. 27, 2011 (CN) 201110444383.8

(51) Int. Cl. H01L 33/36; H01L 33/48

(52) U.S. Cl. 257/88; 438/28; 257/E33.062; 257/E33.056

(57) ABSTRACT

A light emitting diode package includes a triangular supporting member, a first substrate and a second substrate adhered on first and second inclined sidewalls the supporting member, respectively, a first LED chip and a second LED chip secured on the first substrate and the second substrate, respectively, and a package layer covering the first LED chip and a second LED chip. The first inclined sidewall and a bottom surface of the supporting member cooperatively form a first angle therebetween, and the second inclined sidewall and the bottom surface cooperatively form a second angle therebetween. The first angle and the second angle each range between 0 degree and 90 degrees. A method for making the light emitting diode package is also provided.

### BACKGROUND

1. Technical Field

The disclosure generally relates to a light emitting diode package, and a method for making the same.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

When used as light sources of a back light module, the LEDs are required to have a wide light distribution. Generally, a lens is provided on a light emitting surface of each of the LEDs to increase its light emitting angle. However, the lens will increase the cost of and thickness of the LED.

What is needed, therefore, is an LED package to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing an LED package in accordance with a first embodiment of the present disclosure.

FIGS. 2-7 are cross-sectional views showing steps of a method for making the LED package of FIG. 1.

### DETAILED DESCRIPTION

An embodiment of an LED package will now be described in detail below and with reference to the drawings.

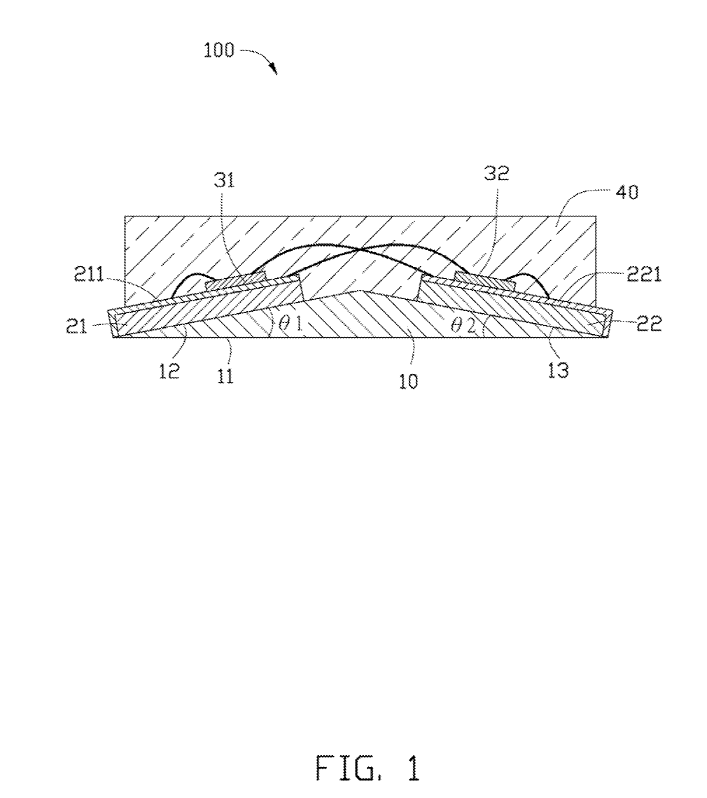

Referring to FIG. 1, an LED package 100 in accordance with an embodiment of the present disclosure includes a supporting member 10, a first substrate 21 and a second substrate 22 both formed on the supporting member 10, a first LED chip 31, a second LED chip 32 and a package layer 40.

The supporting member 10 has a triangular cross section, and includes a bottom surface 11, a first sidewall 12 and a second sidewall 13. A first angle θ1 is formed between the first sidewall 12 and the bottom surface 11, and a second angle θ2 is formed between the second sidewall 13 and the bottom surface 11. The first angle θ1 and the second angle θ2 each range between 0 degree and 90 degrees. In this embodiment, the supporting member 10 is made of a material selected from a group consisting of silicone, SiC and ZnO. The supporting member 10 has an isosceles triangle cross-section, wherein the first angle θ1 is equal to the second angle θ2. Alternatively, the first angle θ1 can also be different from the second angle θ2. Preferably, the first angle θ1 and the second angle θ2 each range from 30 degrees to 60 degrees.

The first substrate 21 is formed on the first sidewall 12 of the supporting member 10, and the second substrate 22 is formed on the second sidewall 13 of the supporting member 10. A first electrode 211 is formed on an upper surface of the first substrate 21 opposite to the supporting member 10. The first electrode 211 further extends downwardly from the upper surface of the first substrate 21 to the bottom surface 11 of the supporting member 10. A second electrode 221 is formed on an upper surface of the second substrate 22 opposite to the supporting member 10. The second electrode 221 further extends downwardly from the upper surface of the second substrate 22 to the bottom surface 11 of the supporting member 10. In this embodiment, the first substrate 21 and the second substrate 22 are made of the same material as the supporting member 10 and selected from a group consisting of silicone, SiC and ZnO. The first substrate 21 and the second substrate 22 are adhered to the first sidewall 12 and the second sidewall 13 of the supporting member 10 respectively.

The first LED chip 31 is formed on an upper surface of the first electrode 211, and the second LED chip 32 is formed on an upper surface of the second electrode 221. The first LED chip 31 is electrically connected with the first electrode 211 and the second electrode 221 via electrically conductive wires (not labeled). Similarly, the second LED chip 32 is also electrically connected with the first electrode 211 and the second electrode 221 via electrically conductive wires (not labled). In this embodiment, light emitted by the first LED chip 31 has the same peak wavelength as that by the second LED 32.

The package layer 40 is formed on the upper surfaces of the first electrode 211 and the second electrode 221 and entirely covers the first LED 31, the second LED 32, the conductive wires and exposed parts of the first and second sidewalls 12, 14 of the supporting member 10. The package layer 40 is configured to prevent the first LED chip 31 and the second LED chip 32 from being affected by steam and dust. The package layer 40 is made of a material selected from a group consisting of silica gel, epoxy resin, polycarbonate and glass. The package layer 40 can further be doped with phosphors to change the color of the light emitted by the first LED chip 31 and the second LED chip 32. The phosphors can be selected from a group consisting of sulfides, silicates, nitrides and garnets.

In the LED package 100 described above, the first angle θ1 between the first sidewall 12 and the bottom surface 11 ranges between 0 degree and 90 degrees. The second angle θ2 between the second sidewall 13 and the bottom surface 11 also ranges between 0 degree and 90 degrees. When the first substrate 21 and the second substrate 22 are attached to the first sidewall 12 and the second sidewall 13 respectively, light from the first LED chip 31 and light from the second LED chip 32 will project towards different directions and thus form a wide light distribution. Therefore, the LED package 100 will have a relatively wide lighting angle.

The LED package 100 can be manufactured by the following steps.

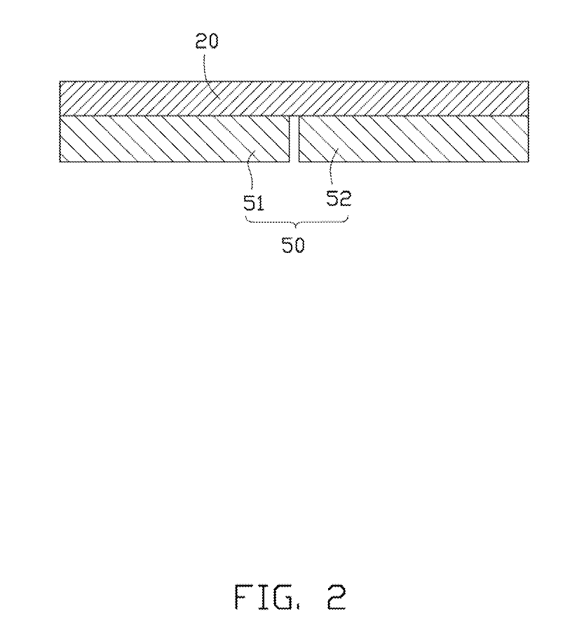

Referring to FIG. 2, a mold 50 is provided. The mold 50 includes a first part 51 and a second part 52 separated from each other. A groove 53 is defined between the first part 51 and the second part 52. Then a substrate 20 is formed on the first part 51 and the second part 52 of the mold 50.

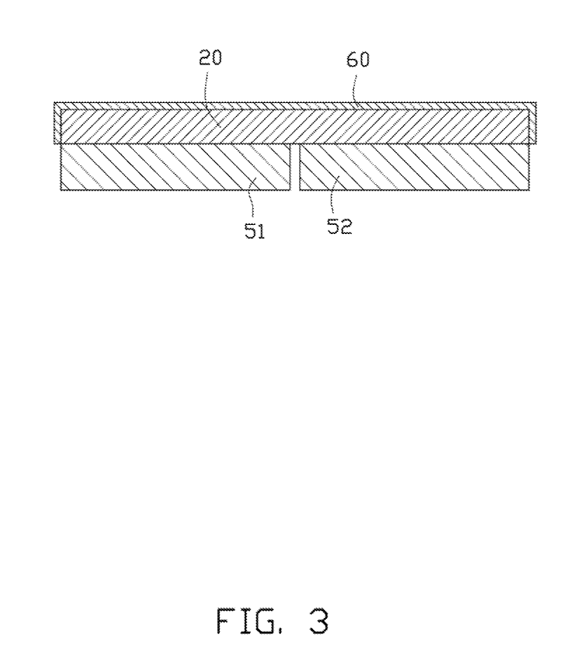

Referring to FIG. 3, a metal layer 60 is formed on an upper surface of the substrate 20 opposite to the mold 50. The metal layer 60 can be made of a material selected from a group consisting of Al (aluminum), Ag (sliver), Cu (copper), Ni (nickel), Pd (palladium) and Au (gold). In this embodiment, the metal layer 60 is formed on the upper surface of the substrate 20 by vacuum evaporation or sputtering. The metal layer 60 can further extend from the upper surface of the substrate 20 to two opposite side surfaces of the substrate 20.

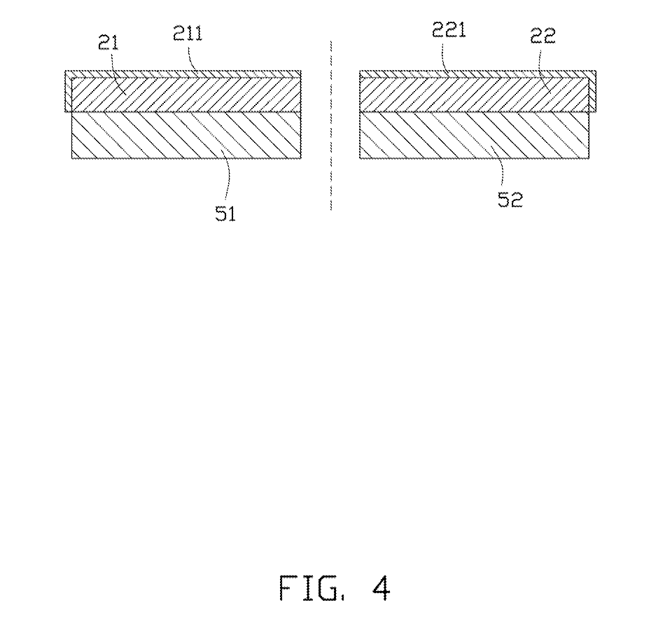

Referring to FIG. 4, the substrate 20 and the metal layer 60 are cut through the groove 53 thereby dividing the substrate 20 into a first substrate 21 and a second substrate 22. In addition, the metal layer 60 is also divided into a first electrode 211 and a second electrode 221. The first substrate 21 is formed on the first part 51 of the mold 50, and the second substrate 22 is formed on the second part 52 of the mold 50. The first electrode 211 and the second electrode 221 are respectively formed on the first substrate 21 and the second substrate 22. In this embodiment, the substrate 20 and the metal layer 60 are separated along the groove 53 between the first part 51 and the second part 52 by mechanical cutting or laser cutting.

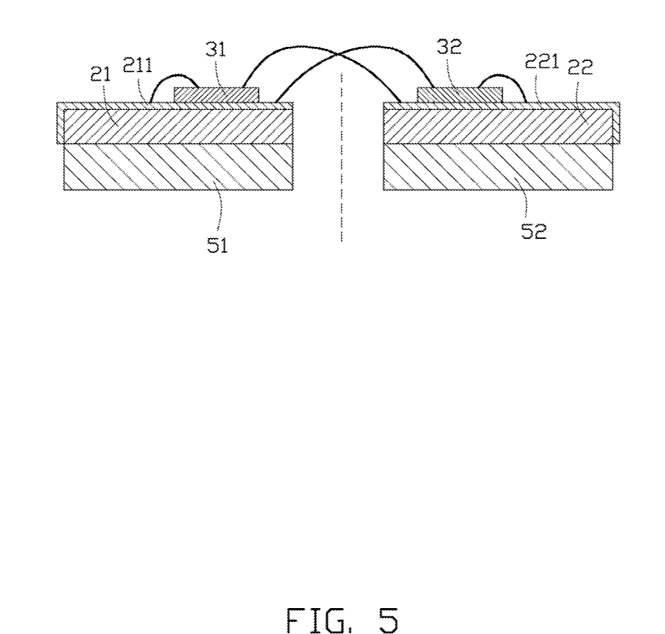

Referring to FIG. 5, a first LED chip 31 is formed on the first electrode 211 and a second LED chip 32 is formed on the second electrode 221. The first LED chip 31 is electrically connected with the first electrode 211 and the second electrode 221 via electrically conductive wires (not labeled). Similarly, the second LED chip 32 is also electrically connected with the first electrode 211 and the second electrode 221 via electrically conductive wires (not labeled).

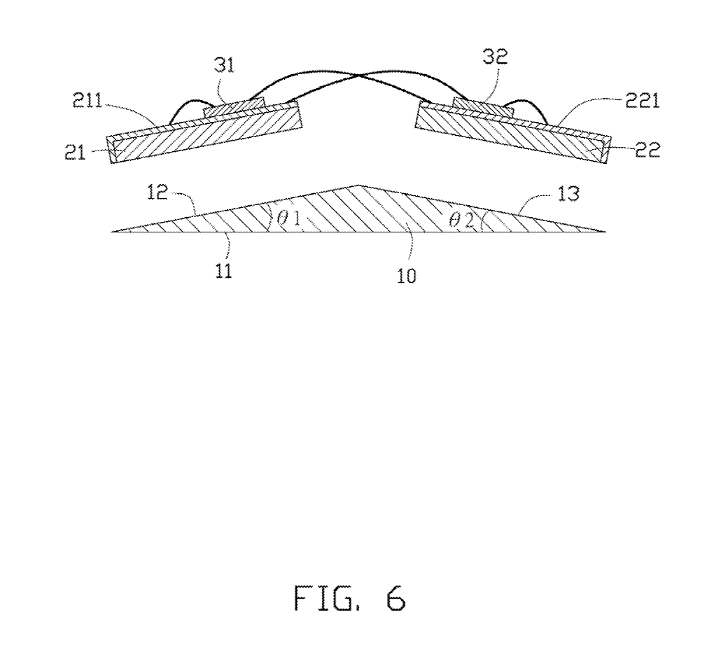

Referring to FIG. 6, the mold 50 is removed from the first substrate 21 and the second substrate 22. A supporting member 10 is then provided. The supporting member 10 includes a bottom surface 11, a first sidewall 12 and a second sidewall 13. The first sidewall 12 and the bottom surface 11 cooperatively form a first angle θ1 therebetween, and the second sidewall 13 and the bottom surface 11 cooperatively form a second angle θ2 therebetween. The first angle θ1 and the second angle θ2 each range between 0 degree and 90 degrees.

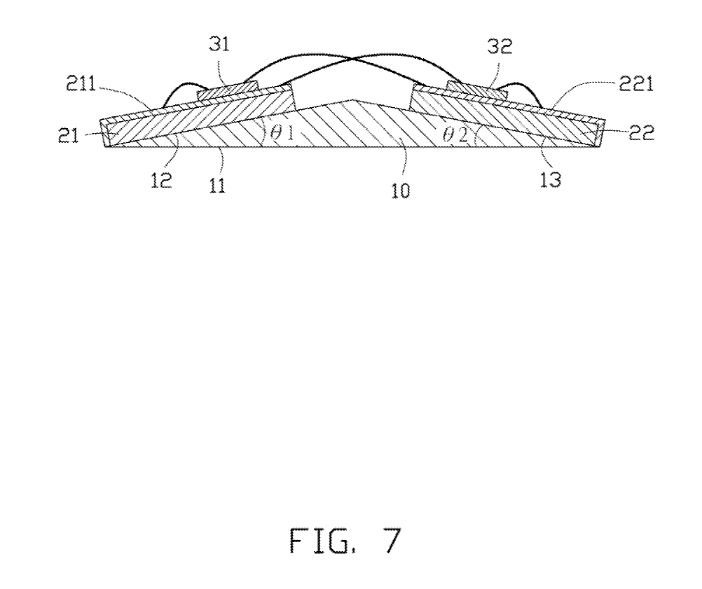

Referring to FIG. 7, the first substrate 21 is secured to the first sidewall 12 of the supporting member 10, and the second substrate 22 is secured to the second sidewall 13. In this embodiment, the first substrate 21 and the second substrate 22 are adhered to the first sidewall 12 and the second sidewall 13 of the supporting member 10 by adhesive glue.

Finally and referring back to FIG. 1, a package layer 40 is formed on upper surfaces of the first electrode 211 and the second electrode 221 and exposed parts of the first and second sidewalls 12, 13 of the supporting member 10. The package layer 40 entirely covers the first LED unit 31 and the second LED unit 32 thereby forming a LED package 100, to prevent the first LED chip 31 and the second LED chip 32 from being affected by steam or dust. The package layer 40 is made of a material selected from a group consisting of silica gel, epoxy resin, polycarbonate or glass. Preferably, the package layer 40 can further be doped with phosphors to change the color of the light emitted by the first LED chip 31 and the second LED chip 32. The phosphors can be selected from a group consisting of sulfides, silicates, nitrides and garnets.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED package, comprising:
a supporting member comprising a bottom surface, a first sidewall and a second sidewall, the first sidewall and the bottom surface cooperatively forming a first angle therebetween, the second sidewall and the bottom surface cooperatively forming a second angle therebetween, the first angle and the second angle each ranging between 0 degree and 90 degrees;
a first substrate and a second substrate formed respectively on the first sidewall and the second sidewall, a first electrode being formed on an upper surface of the first substrate and a second electrode being formed on an upper surface of the second substrate;
a first LED chip and a second LED chip, the first LED chip being formed on an upper surface of the first electrode and electrically connected with the first electrode and the second electrode, the second LED chip being formed on an upper surface of the second electrode and electrically connected with the first electrode and the second electrode; and
a package layer covering the first LED chip and the second LED chip.

2. The LED package of claim 1, wherein the first electrode extends downwardly from the upper surface of the first substrate to the upper surface of the supporting member, and the second electrode extends downwardly from the upper surface of the second substrate to the bottom surface of the supporting member.

3. The LED package of claim 1, wherein light emitted by the first LED chip has a same peak wavelength with light emitted by the second LED chip.

4. The LED package of claim 1, wherein the supporting member is made of a material selected from a group consisting of silicone, SiC and ZnO.

5. The LED package of claim 1, wherein the first substrate and the second substrate each are made of a material selected from a group consisting of silicone, SiC and ZnO.

6. The LED package of claim 5, wherein the first substrate and the second substrate are adhered to the supporting member by adhesive glue.

7. The LED package of claim 1, wherein the first angle between the first sidewall and the bottom surface ranges from 30 degrees to 60 degrees, and the second angle between the second sidewall and the bottom surface ranges from 30 degrees to 60 degrees.

8. The LED package of claim 1, wherein a material of package layer is selected from a group consisting of silica gel, epoxy resin, polycarbonate and glass.

9. A method for manufacturing an LED package, comprising following steps:
providing a mold comprising a first part and a second part;
forming a substrate on the first part and the second part of the mold;
forming a metal layer on an upper surface of the substrate opposite to the mold;
cutting the substrate and the metal layer, thereby dividing the substrate into a first substrate and a second substrate, and dividing the metal layer into a first electrode and a second electrode, the first substrate and the second substrate being formed on the first part and the second part of the mold respectively, the first electrode and the second electrode being formed on the first substrate and the second substrate respectively;
arranging a first LED chip and a second LED chip on the first electrode and the second electrode respectively, and electrically connecting the first LED chip and the second LED chip with the first electrode and the second electrode respectively;
removing the mold from the first substrate and the second substrate;
providing a supporting member, which comprising a bottom surface, a first sidewall and a second sidewall, the first sidewall and the bottom surface cooperatively forming a first angle therebetween, the second sidewall and the bottom surface cooperatively forming a second angle therebetween, the first angle and the second angle each ranging between 0 degree and 90 degrees;
securing the first substrate to the first sidewall and securing the second substrate to the second sidewall; and
forming a package layer entirely covering the first LED chip and the second LED chip.

10. The method of claim 9, wherein a groove is defined between the first part and the second part of the mold, and the cutting of the substrate and the metal layer is along the groove between the first part and the second part of the mold.

11. The method of claim 9, wherein the metal layer extend downwardly from the upper surface of the substrate to the bottom surface of the supporting member.

12. The method of claim 9, wherein light emitted by the first LED chip has a same peak wavelength with light emitted by the second LED chip.

13. The method of claim 9, wherein a material of the supporting member is selected from a group consisting of silicone, SiC and ZnO.

14. The method of claim 9, wherein a material of the first substrate and the second substrate is selected from a group consisting of silicone, SiC and ZnO.

15. The method of claim 14, wherein the first substrate and the second substrate are adhered to the supporting member by adhesive glue.

16. The method of claim 9, wherein the first angle between the first sidewall and the bottom surface ranges from 30 degrees to 60 degrees, and the second angle between the second sidewall and the bottom surface ranges from 30 degrees to 60 degrees.

17. The method of claim 9, wherein a material of package layer is selected from a group consisting of silica gel, epoxy resin, polycarbonate and glass.
